(19) United States
(12) Patent Application Publication
(10) Pub. No.: US 2013/0177995 A1
(43) Pub. Date: Jul. 11, 2013

(54) HIGHLY EPITAXIAL THIN FILMS FOR HIGH TEMPERATURE/HIGHLY SENSITIVE CHEMICAL SENSORS FOR CRITICAL AND REDUCING ENVIRONMENT

(71) Applicant: Board Of Regents Of The University Of Texas System, Austin, TX (US)

(72) Inventors: Chonglin Chen, San Antonio, TX (US); Jian Liu, San Antonio, TX (US)

(73) Assignee: BOARD OF REGENTS OF THE UNIVERSITY OF TEXAS SYSTEM, Austin, TX (US)

(21) Appl. No.: 13/693,880

(22) Filed: Dec. 4, 2012

Related U.S. Application Data
(63) Continuation-in-part of application No. PCT/US2011/039081, filed on Jun. 3, 2011.
(60) Provisional application No. 61/351,576, filed on Jun. 4, 2010.

(51) Int. Cl. G01N 27/04; C30B 23/02; C30B 23/06

(52) U.S. Cl. CPC G01N 27/04; C30B 23/066; C30B 23/025
USPC 436/136; 117/108; 422/98

(57) ABSTRACT

An oxygen sensor includes an epitaxial oxide thin film double perovskite oxygen sensor formed on a single crystal oxide substrate. The thin film includes a lanthanide element, barium, cobalt, and oxygen.

### PRIORITY CLAIM

This application is a Continuation-in-part of International Application No. PCT/US2011/039081, filed Jun. 3, 2011, which claims the benefit of U.S. Provisional Application No. 61/351,576 filed on Jun. 4, 2010.

### STATEMENT REGARDING FEDERALLY SPONSORED RESEARCH OR DEVELOPMENT

This invention was made with government support under grant no. 0709293 awarded by the National Science Foundation and grant no. DE-FG26-07NT43063 awarded by the U.S. Department of Energy. The government has certain rights in the invention.

### BACKGROUND OF THE INVENTION

1. Field of the Invention

The invention generally relates to oxygen sensors. More specifically, the invention relates to semiconductor type oxygen sensors.

2. Description of the Relevant Art

The last decade has brought an explosion in the development of new materials chemistry for ultra-sensitive gas sensors. New chemistry is vital for development of next-generation technology with highly efficient, near zero emission power generation. Three main types of chemical sensors are currently of great interest. The first type is potentiometric gas sensors, which are generally based on the generation of voltage and currents in potentiometric cells employing liquid or solid electrolytes. The most well-known sensors in this category are zirconia stabilized with yttria for automotive exhaust applications. The second type is catalytic calorimeter sensors, which measure the generated heat by utilizing the present amount of combustible gases. The last type, which may be the most active research area in chemical sensors, is resistive sensors fabricated by altering the physical properties of the materials. Such altered physical properties may include electrical conductivity, Hall-effect devices, gate effects in the field effect transistors and metal-oxide-silicon (MOS) structures, Curie points for piezoelectrics, as well as adsorption bands for optical devices.

Compared to other sensors, resistive sensors are characterized by their simple design and easy fabrication. Resistive sensors have received great attention recently because their capacity for achieving a high level of system integration makes them very marketable. Semiconducting metal oxides are promising materials for gas sensors because they exhibit many advantages, which include high sensitivity and selectivity toward specific gas species, simple device fabrication, highly efficient unit operations over a wide range of temperatures and long term stability. The gas-sensing function of semiconducting oxides mainly utilizes the change of the resistivity with the composition of gases. One of the most common models is the chemisorption of oxygen at the surface of the oxide to form O⁻ and the extraction of the electrons at the same time. Substantial changes occur in the conductivity upon adsorption of reducing gases (H₂, CO, CH₃OH) on the surfaces because of the reaction with the O⁻. Since an electron is released upon adsorption, chemisorption of the reducing gases result in the loss of conductivity due to the hole/free electron interaction (assuming an n-type semiconductor). Another process may also happen in parallel with chemisorption, especially at high temperature: the reducing or combustible gas, if chemically active, could react with a lattice oxygen ion and extract it from the metal oxide, leaving the oxygen vacancies as a donor dopant such that the conductivity of the oxide is changed. Both mechanisms, forward or reversed, can be employed when a sensor is designed for different purposes.

For applications in power generation systems, semiconducting oxide sensors usually work in a high temperature environment and mainly employ the reduction-oxidation mechanism. In such cases, suitable materials for sensing should either have a near zero or very high oxygen diffusion constant. With the diffusion constant approaching zero, the oxygen vacancies are limited at the surface; whereas a high diffusion constant allows vacancies to diffuse into the bulk rapidly. Either way, the stoichiometry of the material will reach steady state almost instantly so that the resistance, which is the sensing signal, will become a single value as a function of the target gas pressure and therefore provides good sensitivity. Considering the grain boundary issues for sensors with low bulk mobility, highly ionic conductive sensors are more desirable.

The simple metal oxides commonly used in semiconducting sensors are SnO₂, ZnO, CeO₂, WO₃ and TiO₂. These materials are usually stoichiometric and need certain dopants such as Li(I) or Al(III), or catalysts like Pd to improve the sensor performance. These dopants may raise stability issues at high temperatures. Thus, there has been very few reported high temperature (>500° C.) sensors based on these materials.

Mixed ionic/electronic conducting materials are of potential use in ultra sensitive chemical sensors. Mixed ionic/electronic conducting materials are also of interest for potential applications in various devices such as ceramic membranes, partial oxidation reactors, and electrodes for solid oxide fuel cells (SOFC). To improve the performance of these devices, the mixed ionic/electronic conducting materials may need to meet the requirements of both high oxygen diffusivity and enhancement of surface exchange rate.

One promising candidate for gas sensing applications is perovskite-like oxides. The perovskite-like oxides feature transport properties ranging from predominantly ionic conduction to predominantly electronic conduction. For high-temperature applications, they are particularly attractive because they can provide micro-structural and morphological stability to improve reliability and long-term performance with their high melting and decomposition points. In addition, the two differently-sized cations in the perovskite structure make it amenable to a variety of dopant additions. This doping flexibility allows for control of the transport and catalytic properties, as well as optimizing sensor or electrode performance for particular applications. SrTiO₃ (STO) is the most commonly used perovskite oxide in oxygen sensors; however, STO is highly insulating and therefore the reading of electrical signal with conventional instruments can be significantly complicated.

Desirable attributes may be found in oxygen deficient doped perovskite cobaltates (Re,A)Co₂O_{5+δ}, where Re is a rare earth element and A is an alkaline earth element. The A-site cation average valence favors a compensating population of oxygen vacancies at low oxygen partial pressures and leads to observed high ionic conductivity. (LnBa)CO₂O_{5.5+δ} is one family of compounds that have received significant interest due to many intriguing mixed ionic/electronic conducting phenomena. The nature of the A-site cations, especially their size and their distribution (ordered or disordered), may drastically influence the mixed conductivity. A remarkable enhancement of the oxygen diffusivity in A-site ordered GdBaCo₂O_{5.5+δ} has been observed.

Recent research showed that A-site ordered PrBaCo₂O_{5.5+δ} has unusually rapid oxygen transport kinetics at low temperatures ranging between 300° C. and 500° C. Various interesting physical phenomena have been observed in the perovskite cobaltate family. In particular, the layered perovskite LaBaCo₂O_{5.5+δ} becomes a unique case with some distinctive properties such as the weakest tendency to A-site ordering and smallest oxygen non-stoichiometry due to the small difference between the radii of A-site cations' La³⁺ and Ba²⁺. Recently, groups have fabricated and characterized the fully-oxidized nanoscale-ordered LaBaCo₂O₆, disordered La_{0.5}Ba_{0.5}CoO₃, and the oxygen deficient ordered LaBaCo₂O_{5.5}. They have also observed various interesting new phenomena in this system, such as the unusual magnetization and magnetotransport properties associated with the spin state of cobalt in low temperature.

In addition to their high ionic conductivity and high sensitivity of the resistivity to the oxygen nonstoichiometry, (LnBa)Co₂O_{5.5+δ} also has potential use as a self-catalyst to accelerate the redox reaction, which improves the sensing performance since the compound and its host material, such as LaCoO₃, have shown a high catalytic performance in the oxidation of carbon monoxide and hydrocarbons.

Despite the excellent properties of perovskite cobaltates, their application in gas sensors is limited by the stability of the perovskite phase in a reducing environment at high temperature. The study on the reduction of LnCoO₃ (Ln=La, Pr, Nd, Sm, Gd) perovskites has demonstrated that cobalt reduction occurs in two steps: near 633 K (Co³⁺ to Co²⁺) and at 783 K to 845 K (Co²⁺ to Co⁰). Additionally, the temperature of the second reaction decreases along the periodic chart from La to Gd. Lanthanum, which is the largest ion in the series, forms the most stable perovskite structure during the reaction. Partial substitution of the Ln ion by another ion of a lower oxidation state such as Sr(II) or Ba(II) may also induce important changes in stability. With increasing amount of substitution, the concentration of unstable Co⁴⁺ and oxygen vacancies also increases, which leads to the diffusion of lattice oxygen from the bulk to the surface. Thus, doping with the bivalent ion accounts for the instability of the lattice in a reducing environment. Therefore, the practical application for LnCoO₃ as sensors with or without dopant has been limited by this instability issue at high temperature.

Though there has been a significant amount of development in chemical sensors, there is still a need for a sensor that shows superior stability in high temperature reducing environment and excellent sensitivity to oxygen. Such properties will enable the practical application of low-cost simple-designed resistive sensors in high temperature critical environments that are present in most combustion, gasification, turbines, fuel cells, gas cleaning and separation industrial facilities. Such sensors may also be very marketable with their ability for achieving a high level of system integration.

### SUMMARY OF THE INVENTION

In certain embodiments, a thin film double perovskite epitaxial oxide formed on the single crystal oxide substrate, wherein the thin film oxide comprises a lanthanide element, barium, cobalt, and oxygen. A thin film oxide, generally, has a thickness such that the thin film oxide is capable of undergoing a reversible reaction with oxygen. In some embodiments, the thin film oxide has a thickness of less than 500 nm. In some embodiments, the thin film is formed on the single crystal oxide substrate using pulsed laser deposition. In some embodiments, the thin film is formed on the single crystal oxide substrate using pulsed laser deposition with a wavelength of 248 nm.

In certain embodiments, the thin film is (LnBa)Co₂O_{5+δ}. The oxygen sensor may be operable at temperatures above about 400° C. (e.g., temperatures between about 400° C. and 800° C.). In some embodiments, the oxygen sensor may be operable at temperatures above about 650° C. In some embodiments, the oxygen sensor may be operable at temperatures above about 800° C. The oxygen sensor may be operable in a reducing environment.

In certain embodiments, a method of detecting the presence of oxygen includes locating an oxygen sensor with a thin film of a lanthanide element, barium, cobalt, and oxygen on a single crystal oxide substrate in a sealed chamber and exposing the oxygen sensor to fluid (gas) in the sealed chamber. The oxygen sensor may be exposed to the fluid at temperatures above about 400° C. The oxygen sensor may be operated in a reducing environment.

### BRIEF DESCRIPTION OF THE DRAWINGS

Advantages of the present invention will become apparent to those skilled in the art with the benefit of the following detailed description of embodiments and upon reference to the accompanying drawings in which:

FIG. 1 shows x-ray diffraction patterns from the LaBCO films on various substrates;

FIGS. 2A and 2B depict TEM (transmission electron microscopy) images and selected area electron diffraction (SAED) patterns of (LaBa)Co₂O_{5+δ} films;

FIG. 3A depicts changes in the film resistance when switching from pure oxygen to 4% hydrogen in nitrogen environment;

FIG. 3B depicts the kinetics of the reduction process occurring in the film in more detail;

FIG. 4A depicts the electrical resistivities of (LaBa)Co₂O_{5+δ} films versus temperature in the range of 78 K to 295 K;

FIG. 4B depicts the electrical resistivities of (LaBa)Co₂O_{5+δ} films versus temperature in the range of 295 K to 700 K in 100% oxygen;

FIGS. 5A-5B show the temperature dependence of (LaBa)Co₂O_{5+δ} thin film resistance in 100% N₂ (5A) and 4% H₂/3% H₂O/N₂ (5B);

FIG. 6 shows the relation of sensor response and temperature of the LBCO thin film;

FIGS. 7A-7C show the transient response to a 20 ml air pulse at different injection speeds in the flow of dry 4% H₂/96% N₂ at 780° C.;

FIG. 7D shows the transient response to a 20 ml air pulse in the flow of water saturated 4% H₂ at 780° C.; and

FIGS. 8A-C depicts oxygen and hydrogen sensitivities for different LnBCO films.

While the invention may be susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF THE PREFERRED EMBODIMENTS

It is to be understood the present invention is not limited to particular devices or methods, which may, of course, vary. It is also to be understood that the terminology used herein is for the purpose of describing particular embodiments only, and is not intended to be limiting. As used in this specification and the appended claims, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

In single crystalline thin films, the single crystalline substrate and sharp interfaces may provide extra support for an epitaxial perovskite phase. The structural support may provide enhanced stability in a reducing atmosphere at high temperature, and therefore make fabricating novel highly sensitive chemical sensors possible. The structural support may inhibit irreversible structural change. For example, the single crystalline film's atoms become ‘locked’ in place due to the highly epitaxial growth allowing for the removal or addition of oxygen atoms without material phase change.

In certain embodiments, a thin film double perovskite epitaxial oxide formed on the single crystal oxide substrate, wherein the thin film oxide comprises a lanthanide element, barium, cobalt, and oxygen. As used herein, lanthanide element refers to elements having atomic numbers 57-71, namely: lanthanum, cerium, praseodymium, neodymium, promethium, samarium, europium, gadolinium, terbium, dysprosium, holmium, erbium, thulium, ytterbium, and lutetium. A thin film oxide, generally, has a thickness such that the thin film oxide is capable of undergoing a reversible reaction with oxygen. In some embodiments, the thin film oxide has a thickness of less than 500 nm. In some embodiments, the thin film is formed on the single crystal oxide substrate using pulsed laser deposition. In some embodiments, the thin film is formed on the single crystal oxide substrate using pulsed laser deposition with a wavelength of 248 nm.

In some embodiments, a conductive thin film oxide has the structure (LnBa)Co₂O_{5+δ} where Ln is a lanthanide element.

In certain embodiments, pulsed laser deposition (PLD) is used to form highly epitaxial 112-type layered LnBaCo₂O_{5+δ} (LnBCO) single crystal thin film on single crystal (001) LaAlO₃ (LAO). The LnBCO epitaxial films demonstrate excellent performance and superior stability in both dry and wet hydrogen/nitrogen environments over a wide range of temperatures (e.g., 400° C. up to 780° C.).

In certain embodiments, the PLD system is a KrF excimer PLD system with a wavelength of 248 nm. In some embodiments, the PLD system uses an energy density of 2.0 J/cm² and a laser repetition rate of 5 Hz during film deposition. For LnBCO formation, a (LnBa)Co₂O_{5+δ} target may be used in the PLD system.

In an embodiment, the LnBCO film is formed at 850° C. with an oxygen pressure in the range of 10 mTorr to 250 mTorr. The as-grown films may be annealed in 200 Torr oxygen for 15 minutes at 850° C. and cooled down to room temperature at a rate of 5° C./min. The films may then be individually annealed at 445° C. in a tube furnace under pure oxygen or 4% hydrogen in nitrogen (1 atm) for about three hours.

Microstructure, crystallinity, and epitaxial behavior of the (LnBa)Co₂O_{5+δ} films may be assessed (characterized) using techniques such as X-ray diffraction (XRD) and transmission electron microscopy (TEM). The transport properties of the after-annealed samples may be assessed (measured) by resistance measurements in temperature ranges such as from 78K to 295K and 295K to 700K. The resistance measurements may be assessed using, for example, The Lake Shore Model 370 AC Resistance Bridge. A platinum lead wire for the resistance measurement may be coupled on the sample with silver paste, which may be air dried at room temperature and annealed before measurement.

Conductive (LnBa)Co₂O_{5+δ} thin films may be deposited on various substrates such as (001) LaAlO₃; (001) MgO; (001) SrTiO₃; (110) NdGaO₃; and (001) Si substrates. Deposition, in one embodiment, may be accomplished by using a KrF excimer Pulsed Laser Deposition (PLD) system and/or rf-sputtering system.

In one example, a high density, single phase, stoichiometric (LaBa)Co₂O_{5+δ} target was purchased from Praxair Inc. The deposition is carried out at 850° C. with an oxygen pressure in 10˜250 mTorr in PLD technique and with a 20% O₂ and 80% Ar mixture in an rf-sputtering. The as-grown films were annealed in 200 Torr oxygen for 15 minutes at 850° C. and cooled down to room temperature at a rate of 5° C./min. Microstructural characterization reveals that the as-grown LaBCO films have excellent single crystallinity and a high quality epitaxial nature.

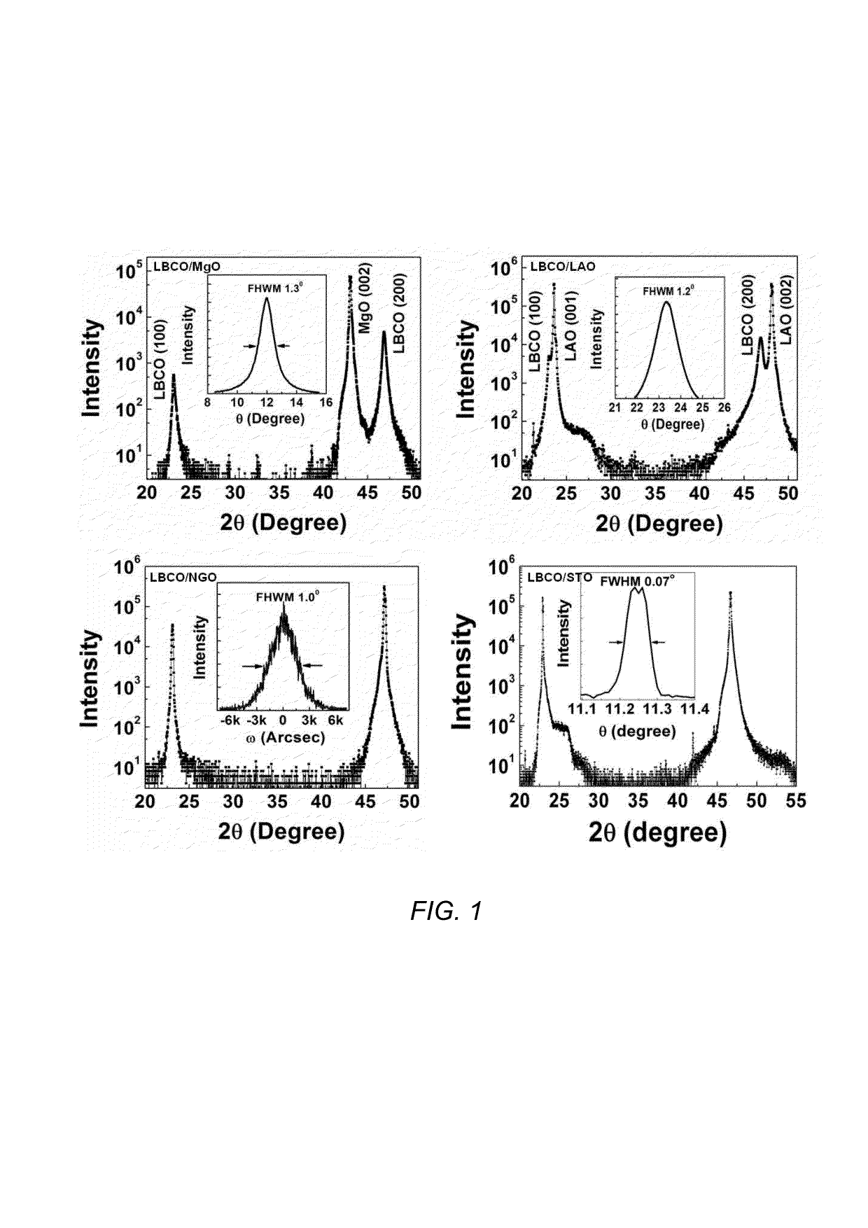

FIG. 1 shows XRD (X-ray diffraction) θ-2θscans of the as-grown (LaBa)Co₂O_{5+δ} thin film deposited on various substrates: (001) MgO; (001) LaAlO₃; (110) NdGaO₃; and (001) SrTiO. Note that all orientations described herein are given in terms of the prototype cubic perovskite structures. The as-grown film was pure (LaBa)Co₂O_{5+δ} phase highly oriented along the c axis with only (00l) peaks observed. The in-plane Φ scan along the <101> directions of the (LaBa)Co₂O_{5+δ} and the substrate revealed that only the {101} reflections separated by 90° were present in the scan with sharp peaks, confirming that the (LaBa)Co₂O_{5+δ} films had excellent single crystallinity, as seen the insets of FIG. 1. The in-plane relationship between the (LaBa)Co₂O_{5+δ} film and the substrate was therefore determined to be [001]_{LaBCO}/[001]_{Substrate} and (100)_{LaBCO}//(100)_{Substrate}. This interface relationship suggests that the as-grown (LaBa)Co₂O_{5+δ} films were cube-on-cube epitaxy.

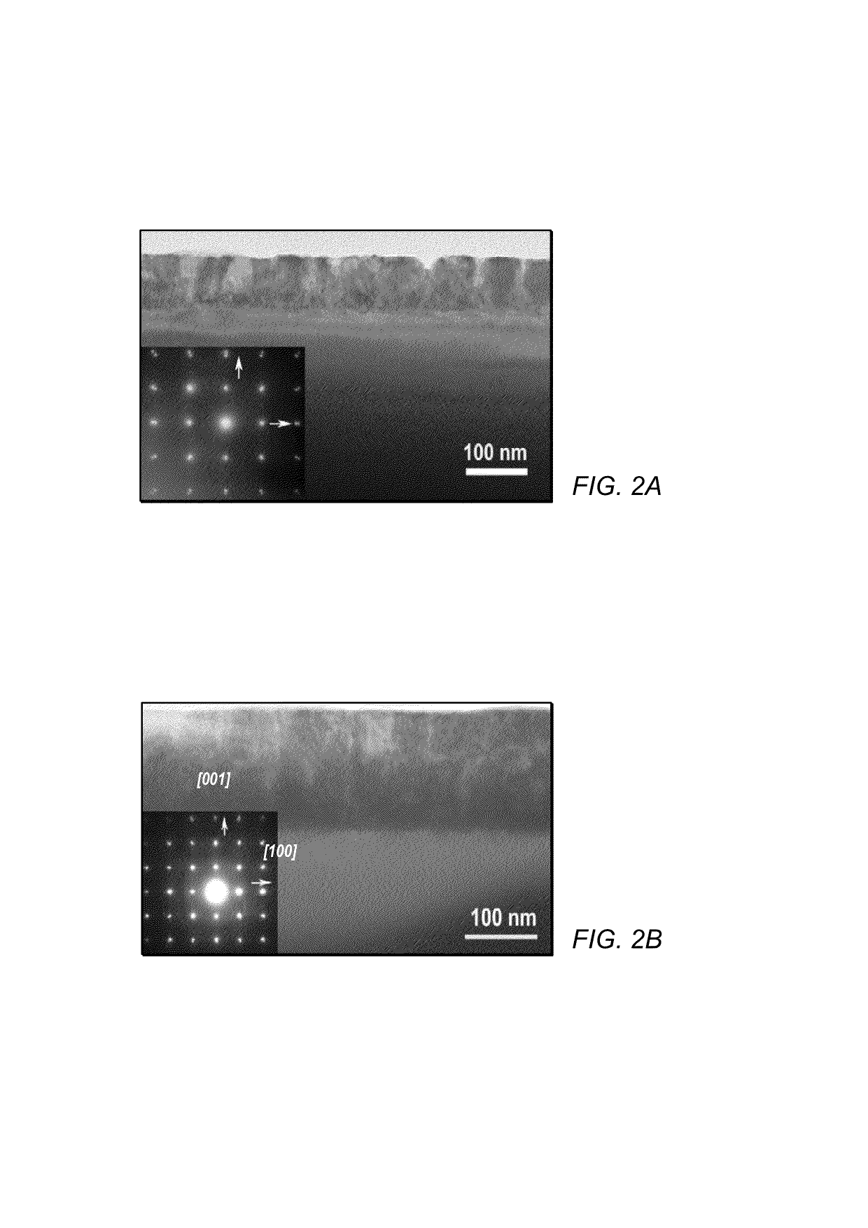

The epitaxial nature and the interface microstructure of the (LaBa)Co₂O_{5+δ} films on (001) LAO were further studied using TEM (transmission electron microscopy). The TEM studies were performed on two (LaBa)Co₂O_{5+δ} films that were post-annealed in either oxygen (FIG. 2A) or hydrogen (4% H₂/96% N₂) (FIG. 2B) at 445° C. As seen in FIGS. 2A and 2B, both the (LaBa)Co₂O_{5+δ} films have smooth surfaces, uniform thicknesses, and clearly defined interfaces with the (001) LAO substrate. The inset of FIG. 2A is the selected area electron diffraction (SAED) pattern taken from the (LaBa)Co₂O_{5+δ}/LaAlO₃ interface annealed in oxygen. The diffraction pattern contained one set of strong reflections corresponding to a cubic cell; however, closer inspection showed the presence of an additional set of weak half-integer reflections indicating a doubling of the perovskite unit cell parameter along the <001>_{C} directions. The (LaBa)Co₂O_{5+δ} film was therefore tetragonal with lattice parameters of c≈2aₚ (a_{P}=the lattice parameter of the corresponding perovskite structure), which was oriented perpendicular to the substrate surface. The superstructure clearly identified along the c axis could be resulted either from the 1:1 ordered stacking of LaO and BaO layers or from the orderly oxygen vacancies in the (LaBa)Co₂O_{5+δ} film. Electron diffraction further confirmed that the interface orientation relationship between the film and substrate was [001]_{LaBCO}//[001]_{LAO} and (100)_{LaBCO}//(100)_{LAO} which was obtained from the X-ray diffraction. Furthermore, the sharp diffraction sports and clean diffraction pattern (no diffusion or extra diffraction spots) indicated that the (LaBa)Co₂O_{5+δ} films had good single crystallinity and excellent epitaxial quality.

A TEM image of the (LaBa)Co₂O_{5+δ} film annealed in 4% hydrogen is shown in FIG. 2B. Although the epitaxial nature and interface relationship of the film with hydrogen treatment was similar to the film treated in oxygen, no superlattice reflections could be observed.

The SAED patterns of both oxygen and hydrogen annealed samples (in the insets of FIGS. 2A and 2B) indicated a slightly distorted tetragonal structure with the out-of-plane lattice parameter (c axis) increased by 1.5% and 2.9%, respectively. Such a distorted lattice was probably due to the compressive stress from the lattice mismatch or the loss of oxygen during the annealing, which is similar to behavior observed for (La,Sr)CoO₃ thin films.

To understand the transport behavior of the (LaBa)Co₂O_{5+δ} films, the changes in the film resistance when switching from pure oxygen to 4% hydrogen in nitrogen environment were monitored by using a highly precise AC resistance bridge at 412° C. The in-plane resistance measurements were carried out with a standard two-probe method using a Lakeshore 370 AC Bridge with silver paste electrode, Pt lead, and 0.1 second measurement interval. The thin film was cut into 8×3 mm² then mounted on an alumina rod with thermocouple and placed in a sealed alumina tube furnace.

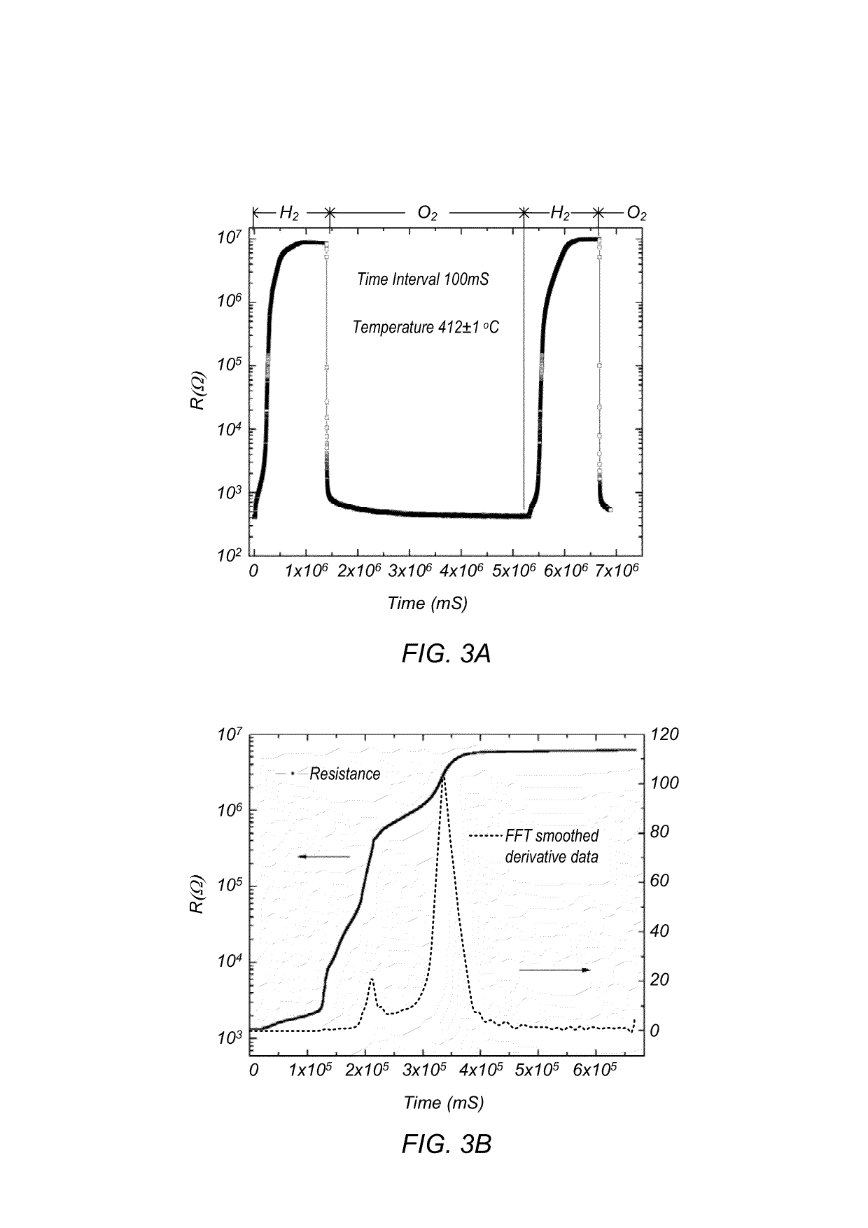

In order for the resistance of (LaBa)Co₂O_{5+δ} film to reach a stable value, the as-grown film was annealed in pure oxygen for three hours. As shown in FIG. 3A, as the gas flow was switched from oxygen to 4% hydrogen in nitrogen, the resistance increased four orders of magnitude, from 10²Ω to 10⁶Ω (ΔR=10⁴Ω). Measurements were made at intervals of 100 ms. The resistance change could be reversed by changing the gas back to oxygen. The kinetics of the reduction process occurring in the film are shown in more detail in FIG. 3B. The resistance change in reducing conditions at such a short time interval suggests that (LaBa)Co₂O_{5+δ} is extremely sensitive to hydrogen. The substantial changes that occur in the conductivity indicate the rapid adsorption of reducing gases (H₂) on the film surface, dissociation of the reducing gases, and reaction of the reducing gases with lattice oxygen to produce water. Since the (LaBa)Co₂O_{5+δ} film was very thin (100 nm), the dominate contribution to the rate of the change in conductivity arises from the surface exchange rate, which can be represented by:

H₂+O²⁻→H₂O+2e⁻

Since electrons are released upon reduction, this process resulted in the decrease of the p-type (LaBa)Co₂O_{5+δ} film conductivity due to the reduction of the concentration of electron holes. The analysis of the shape of the resistance curve showed two different reaction rate peaks in the derivative curve (see FIG. 3B). This may have originated from the various oxidation states of cobalt ions in (LaBa)Co₂O_{5+δ}. For δ≦0.5, Co²⁺:Co³⁺=0.5−δ:0.5+δ, and for δ≧0.5, Co⁴⁺:Co³⁺=δ−0.5:1.5-δ. Thus, the (LaBa)Co₂O_{5+δ} film annealed in oxygen had the lowest oxygen nonstoichiometry with δ≧0.5 and with coexistence of Co⁴⁺ and Co³⁺. The first step in the reduction corresponded to the reduction of Co⁴⁺ to Co³⁺ followed by the reduction of Co³⁺, which was most likely a mixture of Co²⁺ and Co³⁺ oxidation states represented by the composition (LaBa)Co₂O_{5+δ} with δ≦0.5. The hydrogen annealed (LaBa)Co₂O_{5+δ} film became insulator-like with a room temperature resistivity of 2×10⁵Ω·cm as a consequence of the lower concentration of p-type charge carriers on reduction. The reoxidation of the reduced sample is exceedingly fast. The maximum rate of change of the resistance was about 3×10⁶ Ω/s, which was indicative of a rapid surface exchange rate.

### The Temperature Dependence of the Electrical Resistance

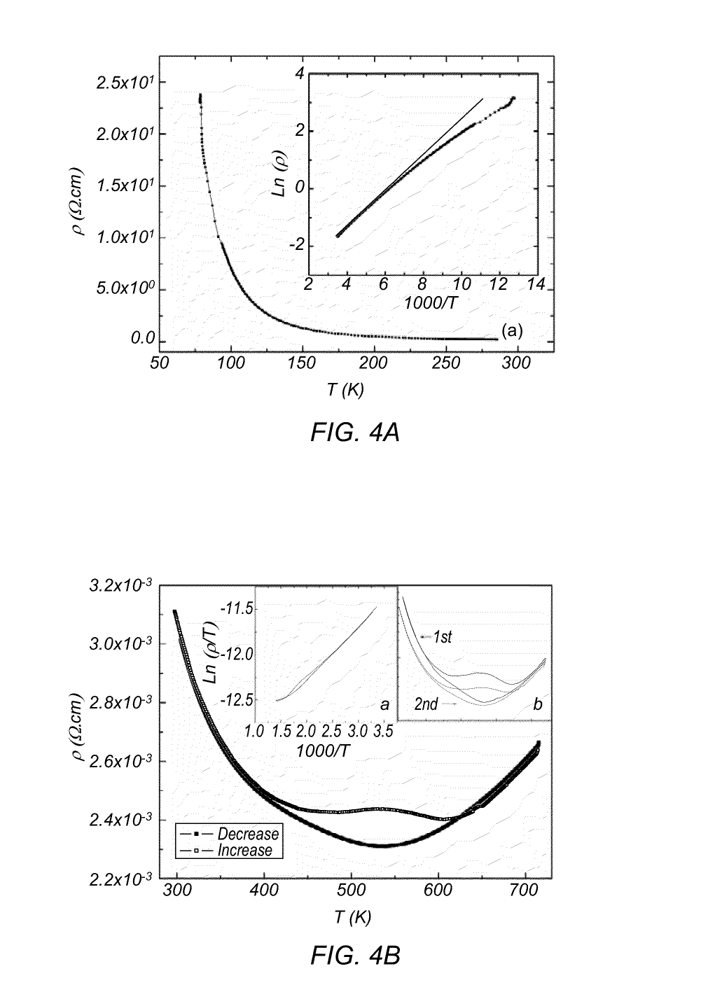

The temperature dependences of the electrical resistance for the ordered layered 112-type (LaBa)Co₂O_{5+δ} films were systematically studied in the temperature ranges of 78 K to 295 K and 295 K to 700 K. The electrical resistivities of (LaBa)Co₂O_{5+δ} films decreased exponentially with the increase of temperature in the range of 78 K to 295 K (see FIG. 4A). This exponential decrease indicated that the (LaBa)Co₂O_{5+δ} films had typical semiconductor behavior at low temperatures. However, the slope from a plot of ln(ρ) versus 1/T plot (inset of FIG. 4A) shows slight dependence on the temperature and slight deviation from a linear relationship. This deviation suggests that the resistance does not have a simple activation behavior, which is possibly due to a transition from low spin state to a thermally excited intermediate-spin state of cobalt ions.

FIG. 4B depicts the electrical resistivities of (LaBa)Co₂O_{5+δ} films measured in 100% oxygen (1 atm) to determine the high temperature (295 K to 700 K) transport properties with the temperature changing at a rate of 3° C./min. The resistivity initially decreased with the increase of temperature and then increased with the increase of the temperature with an upturn transition point at around 540 K. This phenomena probably resulted from the thermal activation in the low temperature range and the loss of oxygen associated with the decrease of the hole concentration at higher temperature. The plot of the ln(ρ/T) versus 1/T can be perfectly fitted linearly from room temperature to the transition point, as seen in inset (a) of FIG. 4B.

An unusual result was observed in the high temperature transport data. A hysteresis gap in the resistance data was observed near the transition point with increasing and decreasing temperature. The resistance change with increasing temperature showed two minimum transition points. Since in the thin film samples the bulk diffusion process can be ignored, this anomaly may have been related to the spin state transitions of the Co³⁺ and Co⁴⁺ ions associated with the oxygen exchange on the surface, which can be represented by Oₒ″ [symbol] Vₒ⁻+½O₂+2e′. The resistance gap decreased with every cycle of measurements carried out under identical conditions (inset (b) of FIG. 4B). This indicated that the oxygen exchange process was not fully reversible and the concentration of Co (IV) may play an important role in these phenomena.

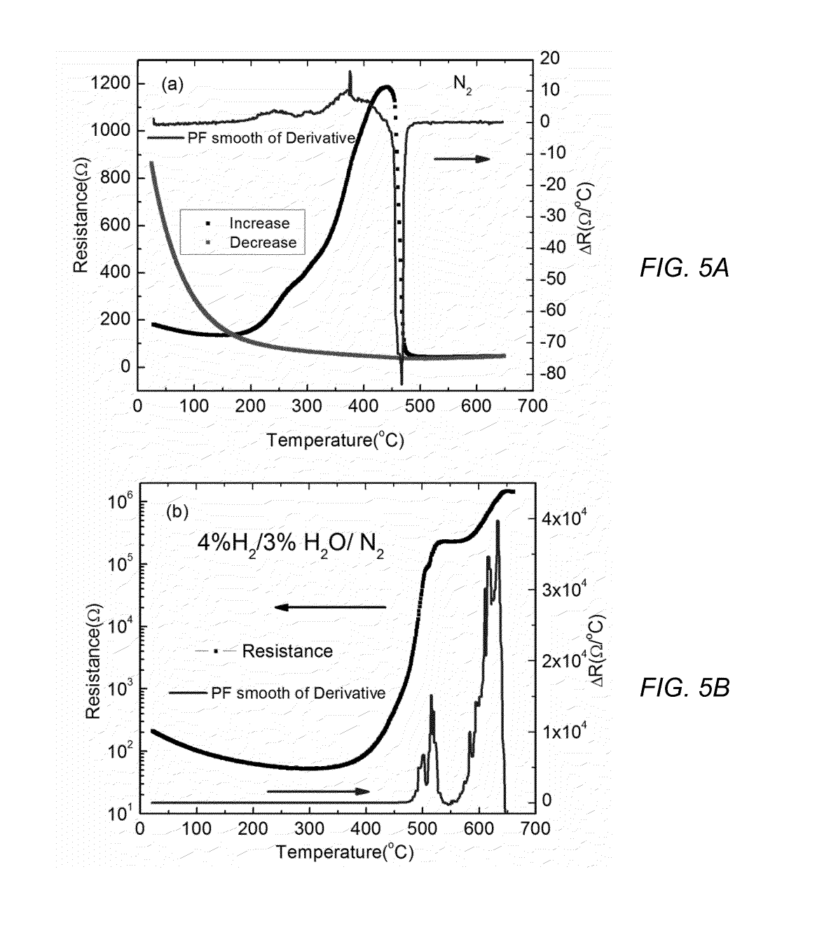

The temperature dependence of the resistance in a mildly reducing environment was characterized on the as-grown LaBCO thin film in pure nitrogen, (P_{O2}≦1×10⁻⁵ atm) (FIG. 5A). It is interesting to note that as the sample undergoes its first temperature increasing process (˜1° C./min), an abnormal increase of resistance was found to start at 150° C. and reach a maximum at 442° C. followed by a sudden drop.

The first order derivate analysis of the resistance reveals that the first change process occurs in the temperature interval of 150˜300° C. which can be attributed to the loss of adsorbed oxygen molecular: O_{ad}²⁻→½O_{2(g)}+2e⁻. The released electrons interact with the charge carrier hole in p-type semiconducting LBCO resulting in the loss of conductivity. The second resistance change, between 300˜440° C., with the resistance being almost tripled, is associated with the reduction of the cobalt ion. In LBCO, partial substitution of La³⁺ with Ba²⁺ introduces unstable Co⁴⁺ and oxygen vacancies V_{O}^{••}. Oxygen deficiencies can be generated when Co⁴⁺ transfers into Co³⁺ and Co³⁺ to Co²⁺, the reaction can be expressed as

2O²⁻+2Co³⁺+Co⁴⁺ [symbol] 2V_{O}^{••}+3Co²⁺+O₂(g) (1)

Therefore, the electrons associated with the generated oxygen vacancy compensate the holes and reduce the conductivity. But interestingly, with the temperature further increased from 440 to 494° C., the resistance undergoes a drastic drop. Although the mechanism of the sudden resistance drop during this heating process remains unclear, this phenomenon may somewhat relate to the reduction of the stoichiometric LaBaCo₂O₆ in to LaBaCo₂O_{5.5}, reported in the previous studies. This evidence indicates that the complete reduction of Co⁴⁺ to Co³⁺ can result in an oxygen stoichiometry very close to 5.5. Thus, due to the comparable crystal field energy and the intra-atomic exchange energy, the low spin, intermediate spin and high spin states of Co³⁺ may coexist in perovskite structure. The oxygen deficient concentration and distribution also influences the chemical environment of the cobalt ion. Therefore, this irregular resistance behavior can be attributed to the coupling between the reduction of Co⁴⁺ to Co³⁺ and the spin state transition of Co³⁺ in the epitaxial LBCO thin films.

The conductivity behavior of LBCO thin film was further studied in water saturated 4% H₂/N₂ (FIG. 5B). Two major resistance changing processes occur at 470-550° C. and 570-645° C., which correspond to the reduction of Co³⁺ to Co²⁺ and Co²⁺ to Co⁰, where the resistance is first increased from 10³ to 10⁵Ω and finally reaches 10⁶Ω. Since the reduced metal Co should be in a highly dispersed state on a matrix composed of the oxide, the high resistance of the reduced sample is the result of an absence of conductive Co—O layers in the crystal structure. Each resistance changing rate peak is split into two parts, indicating two slightly different reducing temperatures. The distribution of oxygen vacancies and co-existent A-site ordered and disordered phases of LBCO film leads a significant diversity of oxygen exchange and chemical properties of the cobalt ion, and is reflected in this reduction process.

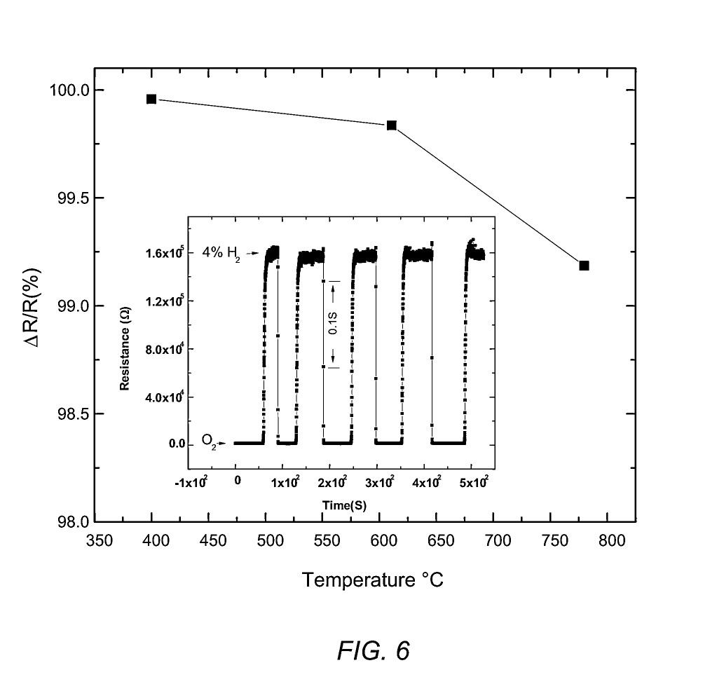

The conductivity of the reduced LBCO thin film can be fully recovered by re-oxidizing in pure oxygen. The resistance change was measured during the reduction-reoxidation cycles in the temperature range of 400˜780° C. with a time interval of 100 ms (inset of FIG. 6)). The resistance response is expressed as ΔR/R_{H} (%) where R_{H} is the reference resistance in 4% H₂/96% N₂, and its relationship with temperature is shown in of FIG. 6. The film exhibits over 99% response to the pure oxygen with the response time, defined as the time necessary to reach 90% of the final resistance, varying from 8 seconds (400° C.) to 0.5 second (780° C.). The response time of LBCO epitaxial thin film is about one order lower than the previously reported sensor performance at ˜400° C. It is important to note that the response time of LBCO system in reducing H₂ environment is comparable with the Mg-doped SrTiO₃ sensor in N₂ environment at high temperature.

According to the Goldschmidt tolerance factor obtained for LnCoO₃ system, if only considering the geometric factors, lanthanum forms the most stable perovskite structure, so that the re-oxidation of reduced cobalt to form the perovskite structure is more favorable for LaCoO₃. Because Ba²⁺ and La³⁺ have very close ionic size, the same conclusion should apply to (LaBa)Co₂O_{5+δ}. Also, the reduced LBCO thin film contains a high density of oxygen vacancies with quick diffusion speed. Considering the thin film thickness (150 nm), the reaction of oxygen and oxygen vacancy could reach equilibrium instantly in the presence of the oxygen molecules in the gas phase. With the catalytic activation of oxygen molecular by cobalt, the re-oxidation reaction of LBCO thin film is sped up thermodynamically and kinetically, so that this drastic resistance change can be achieved within such a short time and indicates its potential application to high temperature resistive gas sensors.

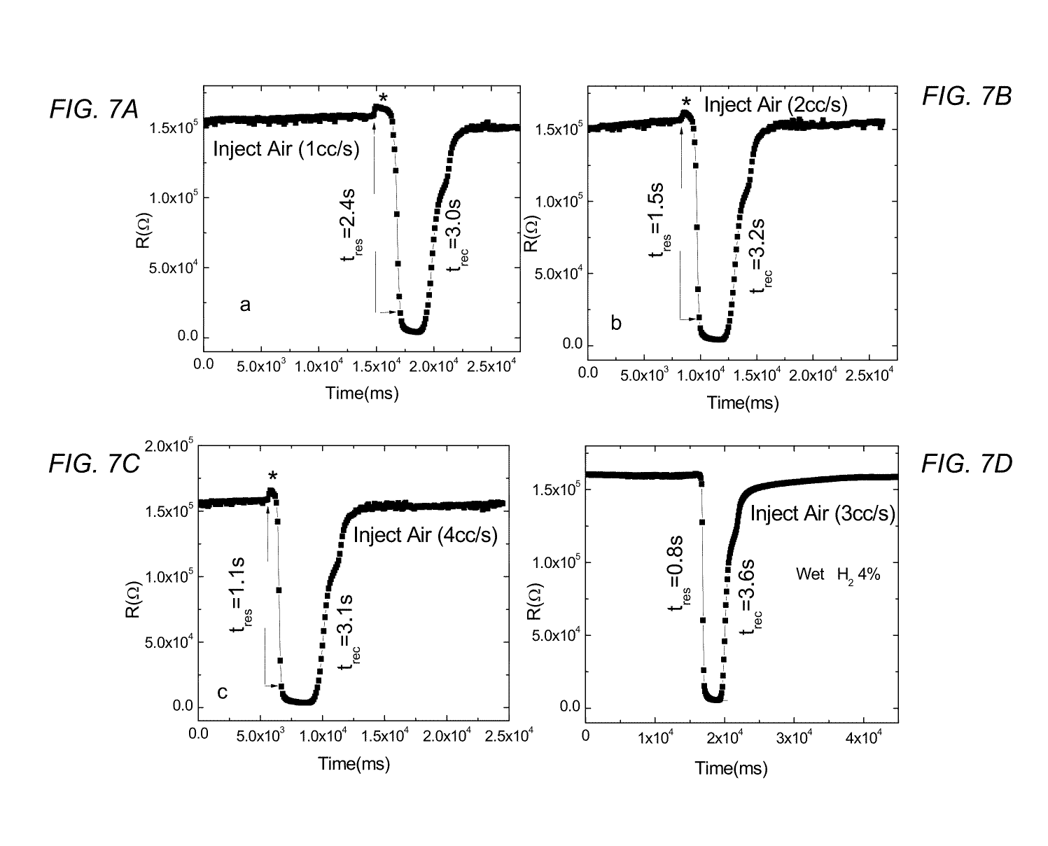

FIGS. 7A-7D show the transient response to the 20 ml air pulse at different injection speeds in the flow of dry 4% H₂/96% N₂ at 780° C. A fully reversible resistance change was observed. The response time (tᵣₑₛ) varied from 1.1 second to 2.4 seconds with lower injection speed. A very remarkable result concerning the response process was that there was a resistance peak (marked with *) that appeared as soon as the air was injected and before the drastic decrease of resistance. On the other hand, when the identical measurement was carried out with water saturated gas, the peak was diminished and the response time became shorter (shown in FIG. 6D). Considering the high test temperature, it could be concluded that this phenomenon resulted from the water produced by the reaction of hydrogen and the incoming oxygen. The recovery time was about 3.1±0.1 seconds for all tests under dry gases and a little longer with the wet gases, which could be explained in that the recovery process was essentially a hydrogen reduction reaction with water as a product. Thus, the wet environment could slow down the reaction rate.

The hydrogen reduced LBCO film became insulator-like. At room temperature the resistance was on the order of 10¹⁰Ω and during the test it varied from 10⁶ to 10⁵Ω as the temperature increased. With p-type conduction, the reduction of LBCO results in the loss of conductivity due to the hole-free electron interaction. The principle of oxygen sensor response can be stated as follows: at high temperature, the reduced LBCO thin film contains a high density of oxygen vacancies, which diffuse quickly from the interior of the film to the surface. Considering the thin film sample has only 150 nm thickness, the addition of these diffused vacancies makes little contribution to the change of the surface oxygen vacancy concentration. Therefore, in the presence of oxygen molecules in the gas phase, the reaction of oxygen and oxygen vacancy may reach equilibrium almost instantly. Simultaneously, the reaction may consume electrons and increase the concentration of hole-charge carrier. Thus, the conductivity may be drastically increased. In addition to the high sensitivity, the LBCO thin film also showed superior stability in reducing environment at high temperature. The study of the reduction of LaCoO₃ perovskite bulk material demonstrated that the cobalt ion is fully reduced at about 845 K. Also, the partial substitution of the La³⁺ ion by a lower oxidation state such as Sr has accounted for the enhanced instability of the lattice in a reducing environment. The high temperature stability of LBCO thin film in reducing environment may be due to the thinness of the film combined with the sharp stable interface with the single crystal LaAlO₃ substrate.

Highly epitaxial 112-type layered (LaBa)Co₂O_{5+δ} single crystalline thin films were successfully grown on various substrates by using pulsed laser deposition. The microstructure characterizations from X-ray diffraction (XRD) and electron microscopy indicated that the films were either A cation ordered or oxygen vacancy ordered and they were highly a-axis oriented with cube-on-cube epitaxy. The interface relationship was determined to be [001]_{LBCO}//[001]_{LAO} and (100)_{LBCO}//(100)_{LAO}. Transport property measurements indicated that the films had typical semiconductor behavior with a novel phase transition and hysteresis phenomena at 540 K.

In addition, chemical dynamic studies revealed that the resistance of the film changed drastically with the change of redox environment. Large magnitude of resistance changes (ΔR=10² [symbol] 10⁶Ω) were found within an extremely short response time. These phenomena show that the as-grown (LnBa)Co₂O_{5+δ} films have extraordinary sensitivity to reducing-oxidizing environment and exceedingly fast surface exchange rate. These results suggest that the epitaxial (LnBa)Co₂O_{5+δ} thin films can be a promising candidate for ultra-sensitive chemical gas sensors and cathode components for IT-S OFCs (intermediate temperature solid oxide fuel cells).

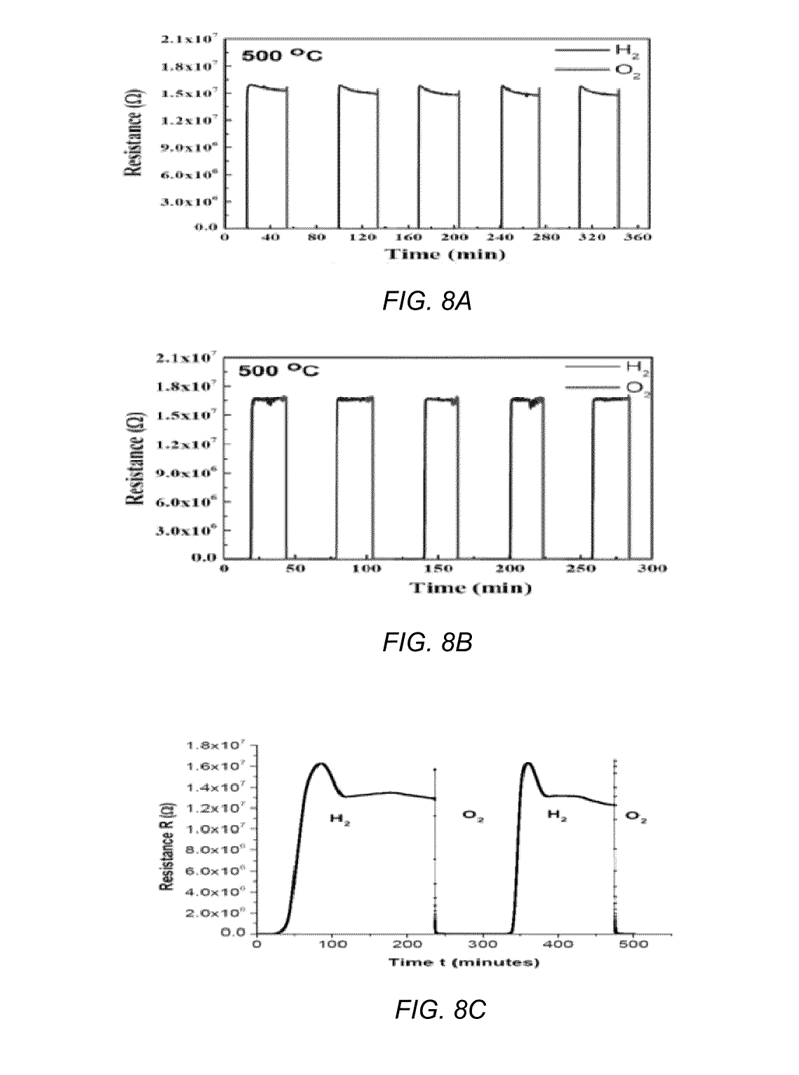

FIGS. 8A-8C depict oxygen and hydrogen sensitivities of various LnBCO thin films. FIG. 8A depicts the oxygen and hydrogen sensitivity for a PrBaCo₂O_{5.5} thin film. FIG. 8B depicts the oxygen and hydrogen sensitivity for an ErBaCo₂O_{5.5} thin film. FIG. 8C depicts the oxygen and hydrogen sensitivity for a CaBaCo₂O_{5.5} thin film. Thin films made using lanthanide elements show a much cleaner transition from low to high resistivity (FIGS. 8A and 8B) in comparison to the alkali metal (Ca) thin film (FIG. 8C).

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. An oxygen sensor, comprising:
a single crystal oxide substrate,
a thin film double perovskite epitaxial oxide formed on the single crystal oxide substrate, wherein the thin film oxide comprises a lanthanide element, barium, cobalt, and oxygen;
wherein the thin film oxide has a thickness such that the thin film oxide is capable of undergoing a reversible reaction with oxygen.

2. The oxygen sensor of claim 1, wherein the thin film oxide comprises (LnBa)Co₂O_{5+δ} where Ln is a lanthanide element.

3. The oxygen sensor of claim 1, wherein the thin film oxide comprises (LaBa)Co₂O_{5+δ}.

4. The oxygen sensor of claim 1, wherein the single crystal oxide substrate comprises LaAlO₃.

5. The oxygen sensor of claim 1, wherein the thin film oxide has a thickness of less than 500 nm.

6. A method of making an oxygen sensor comprising: forming a thin film double perovskite epitaxial oxide on a single crystal oxide substrate, wherein the thin film oxide comprises a lanthanide element, barium, cobalt, and oxygen.

7. The method of claim 6, wherein the thin film oxide is formed on the single crystal oxide substrate using pulsed laser deposition.

8. The method of claim 6, wherein the thin film oxide is formed on the single crystal oxide substrate using pulsed laser deposition with a wavelength of 248 nm.

9. The method of claim 6, wherein the thin film oxide comprises (LnBa)Co₂O_{5+δ} where Ln is a lanthanide element.

10. The method of claim 6, wherein the thin film oxide comprises (LaBa)Co₂O_{5+δ}.

11. The method of claim 6, wherein the single crystal oxide substrate comprises LaAlO₃.

12. The method of claim 6, wherein the thin film oxide has a thickness of less than 500 nm.

13. A method of detecting the presence of oxygen, comprising:
locating an oxygen sensor comprising a thin film double perovskite epitaxial oxide comprising a lanthanide element, barium, cobalt, and oxygen on a single crystal oxide substrate in the presence of an oxygen containing gas; and
exposing the oxygen sensor to the oxygen containing gas.

14. The method of claim 9, further comprising exposing the oxygen sensor to the oxygen containing gas at temperatures above about 400° C.

15. The method of claim 9, further comprising operating the oxygen sensor in a reducing environment.

16. The method of claim 9, wherein the oxygen sensor is positioned in a sealed chamber that contains the oxygen containing gas.

17. The method of claim 9, wherein the thin film oxide comprises (LnBa)Co₂O_{5+δ} where Ln is a lanthanide element.

18. The method of claim 9, wherein the thin film oxide comprises (LaBa)Co₂O_{5+δ}.

19. The method of claim 9, wherein the single crystal oxide substrate comprises LaAlO₃.

20. The method of claim 9, wherein the thin film oxide has a thickness of less than 500 nm.
